(19) United States
(12) Patent Application Publication
(10) Pub. No.: US 2024/0130143 A1
(43) Pub. Date: Apr. 18, 2024

(54) MEMORY AND STORAGE ON A SINGLE CHIP

(71) Applicant: Micron Technology, Inc., Boise, ID (US)

(72) Inventors: Innocenzo Tortorelli, Cernusco sul Naviglio (MI) (IT); Agostino Pirovano, Milano (MI) (IT); Matteo Impalà, Milano (MI) (IT); Mattia Robustelli, Milano (MI) (IT); Fabio Pellizzer, Boise, ID (US)

(21) Appl. No.: 17/968,744

(22) Filed: Oct. 18, 2022

(51) Int. Cl. H01L 27/24; H01L 45/00

(52) U.S. Cl. CPC H01L 27/2481; H01L 45/06; H01L 45/143; H01L 45/1683

(57) ABSTRACT

A single memory chip including both memory and storage capabilities on the single chip and accompanying process for forming a memory array including both capabilities is disclosed. In particular, the single chip may incorporate the use of two different chalcogenide materials deposited thereon to implement the memory and storage capabilities. Chalcogenide materials provide flexibility on cell performance, such as by changing the chalcogenide material composition. For the single memory chip, one type of chalcogenide material may be utilized to create memory cells and another type of chalcogenide material may be utilized to create storage cells. The process for forming the memory array includes forming first and second openings in a starting structure and performing a series of etching and deposition steps on the structure to form the memory and storage cells using the two different chalcogenide compositions. The memory and storage cells are independently addressable via wordline and bitline selection.

### FIELD OF THE TECHNOLOGY

At least some embodiments disclosed herein relate to memory devices in general, and more particularly, but not limited to, a single chip incorporating both a memory and a storage on the single chip.

### BACKGROUND

Typically, a computing device or system includes one or more processors and one or more memory devices, such as memory chips or integrated circuits. The memory devices may be utilized to store data that may be accessed, modified, deleted, or replaced. The memory devices may be, for example, non-volatile memory devices that retain data irrespective of whether the memory devices are powered on or off. Such non-volatile memories may include, but are not limited to, read-only memories, solid state drives, and NAND flash memories. Additionally, the memory devices may be volatile memory devices, such as, but not limited to, dynamic or static random-access memories, which retain stored data while powered on, but are susceptible to data loss when powered off. Based on receipt of an input, the one or more processors of the computing device or system may request that a memory device of the computing system retrieve stored data associated with or corresponding to the input. In certain scenarios, the data retrieved from the memory device may include instructions, which may be executed by the one or more processors to perform various operations and may include data that may be utilized as inputs for the various operations. In instances where the one or more processors perform operations based on instructions from the memory device, data resulting from the performance of the operations may be subsequently stored into the memory device for future retrieval.

Often, a memory device, such as a chip, may include memory cells to implement short-term data access, such as provided by dynamic random-access memory or other similar technologies. A separate chip may separately include storage cells that are utilized to store and access data on a persistent or long-term basis. Having such componentry on separate chips or memory devices contributes to increased costs, potentially increased risk of inoperability between separate chips, reduced space on a printed circuit board or other device which incorporates the chips, and potentially increased complexity. Based at least on the foregoing, existing memory cell and storage cell technologies may be enhanced to facilitate space savings, reduced potential costs, increased operability, greater integration, among various other benefits.

### BRIEF DESCRIPTION OF THE DRAWINGS

The embodiments are illustrated by way of example and not limitation in the figures of the accompanying drawings in which like references indicate similar elements.

FIG. 1 shows an exemplary memory device and host device in accordance with embodiments of the present disclosure.

FIG. 2 shows an example of a memory cell that includes a select device in accordance with embodiments of the present disclosure.

FIG. 3 shows an exemplary memory device including memory area and storage area on a single chip in accordance with embodiments of the present disclosure.

FIG. 4 illustrates exemplary characteristics and chalcogenide materials that may be utilized to implement memory areas and storage areas for a memory array for a chip in accordance with embodiments of the present disclosure.

FIG. 5A illustrates silicon, silicon nitride, and silicon dioxide layers forming a base utilized in a process for creation of a memory array to include storage cells and memory cells on a single chip according to embodiments of the present disclosure.

FIG. 5B illustrates a next step in the process for creation of the memory array that includes creating pier openings for the memory array according to embodiments of the present disclosure.

FIG. 5C illustrates a next step in the process for creation of the memory array that includes conducting pier deposition and creating pillar openings for the memory array according to embodiments of the present disclosure.

FIG. 5D illustrates next steps in the process for creation of the memory array that includes conducting a silicon nitride stripping process, tungsten deposition, and tungsten recession on the memory array according to embodiments of the present disclosure.

FIG. 6A illustrates next steps in the process for creation of the memory array that include bottom electrode deposition and placeholder deposition on the memory array according to embodiments of the present disclosure.

FIG. 6B illustrates next steps in the process for creation of the memory array that include top electrode deposition and pillar tungsten filling on the memory array according to embodiments of the present disclosure.

FIG. 7A illustrates polysilicon and silicon dioxide removal for visual illustration purposes.

FIG. 7B illustrates the polysilicon and silicon dioxide included on the memory array for visual illustration purposes.

FIG. 8 illustrates next steps in the process for creation of the memory array that include creating a first opening to create storage cells for the storage select device in the memory array, etching polysilicon to access placeholder material to be replaced, conducting placeholder recission and storage select device deposition according to embodiments of the present disclosure.

FIG. 9A illustrates next steps in the process for creation of the memory array the include creating a second opening to create memory cells for the memory select device in the memory array, conducting a polysilicon etch to access placeholder material, placeholder recession, and memory select device deposition according to embodiments of the present disclosure.

FIG. 9B illustrates FIG. 9A with the silicon dioxide layer removed for visual illustration purposes so that the memory select device storage cells may be visualized readily.

FIG. 10 illustrates the completed and final memory array including the memory select device storage cells and the storage select device storage cells, where the silicon dioxide layer is removed for visual illustration purposes.

FIG. 11 illustrates a method for incorporating memory and storage elements, distinguished by different select device deposited chalcogenide compositions, within the same memory array in accordance with embodiments of the present disclosure.

### DETAILED DESCRIPTION

The following disclosure describes various embodiments for systems and methods for incorporating memory capabilities and storage capabilities jointly on a single memory device, such as a memory chip. In particular, the systems and methods described facilitate creation and operation of a single memory chip including a memory array including both memory and storage capabilities on the single memory chip is disclosed. In certain embodiments, the single memory chip may incorporate the use of two different chalcogenide material compositions deposited thereon to implement the memory and storage capabilities. Chalcogenide materials may be utilized because chalcogenide materials provide flexibility regarding memory and storage cell performance, such as by adjusting the chalcogenide material compositions. For the single memory chip disclosed herein, one type of chalcogenide material may be utilized to create memory cells and another type of chalcogenide material may be utilized to create storage cells. The process for forming the memory array includes forming openings in an initial base memory array structure and performing a series of etching and deposition steps on the structure to form and incorporate the memory and storage cells using the two different chalcogenide compositions. In certain embodiments, the process for forming the memory array may include utilizing a sequence of pier opening steps that may be utilized to differentiate the silicon area on the single chip using two different atomic layer depositions (ALD) compositions. In certain embodiments, the memory and storage cells may be configured to be independently addressable via wordline and bitline selection. Based on at least the foregoing, the embodiments of the present disclosure provide significant enhancement to memory device technologies including providing a system, memory device (e.g., a chip), and accompanying methods for incorporating both memory cells and storage cells on the same single chip through the use of different chalcogenide material compositions.

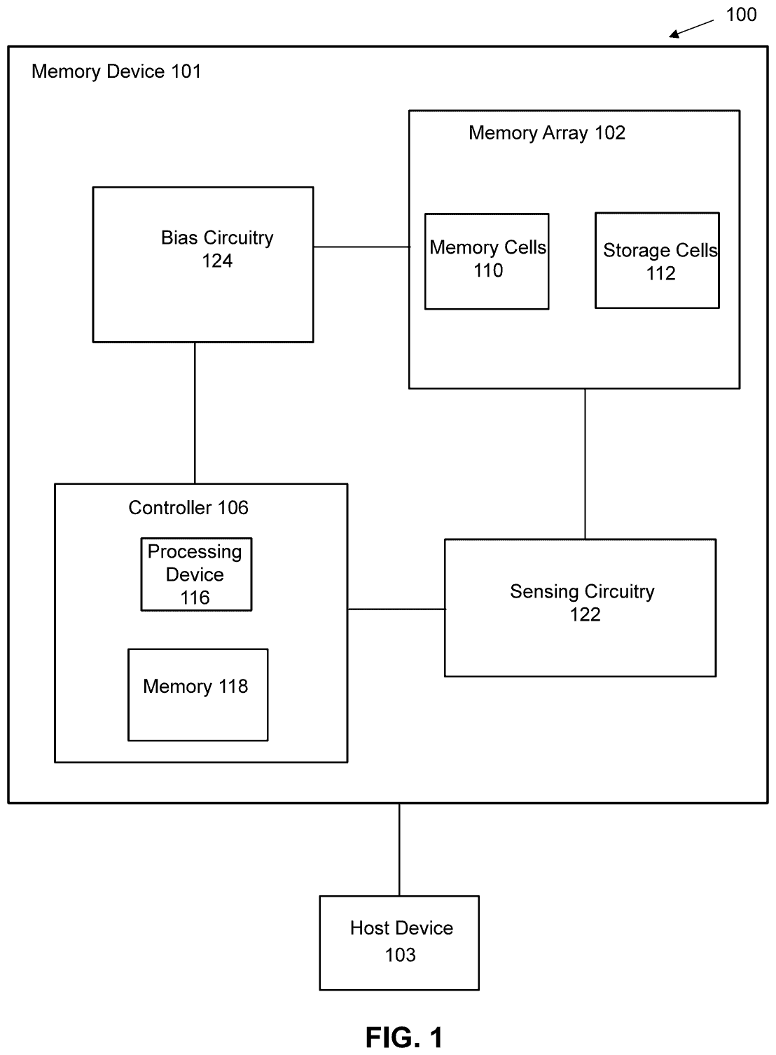

Referring now also to FIG. 1, FIG. 1 illustrates an exemplary architecture for a system 100 including a memory device 101 and host device 103 that may incorporate memory and storage on a single chip accordance with embodiments of the present disclosure. The memory device 102 and other componentry illustrated in the Figures may belong to a system 100. In certain embodiments, the memory device 101 may include, for example, but not limited to, an SSD, Phase Change Memory (PCM), Managed Storage (SCM), Storage+, eMMC, memory card, or other storage device, or a NAND-based flash memory chip or module, or a combination thereof. In certain embodiments, the memory device 101 may include any amount of componentry to facilitate the operation of the memory device 101. In certain embodiments, for example, the memory device 101 may include, but is not limited to including, a non-volatile memory, which may include any number of memory blocks, a volatile memory, a memory interface, a controller 106 (which may include counters 104, processing device 116, and a memory 118), a hardware security module, any other componentry, or a combination thereof. The memory device 101 may communicatively link with a host device 103, which may be or include a computer, server, processor, autonomous vehicle, any other computing device or system, or a combination thereof. In certain embodiments, a non-volatile memory of the memory device 101 may be configured to retain stored data irrespective of whether there is power delivered to the non-volatile memory. In certain embodiments, the non-volatile memory may be configured to include any number of memory blocks that may be configured to stored user data.

In certain embodiments, the controller 106 of the memory device 101 may be configured to control access to the non-volatile memory, the volatile memory, other memory of the memory device 101, or a combination thereof. In certain embodiments, the controller 106 may be configured to include a processing device 116 configured to process operations, commands, and data, such as those coming from the host device 103. In certain embodiments, the controller 106 may include a memory 118, where potentially firmware supporting the operative functionality of the memory device 101 may be stored. Additionally, other modules and data structures may be stored within the memory 118 that may be utilized to support the operative functionality of the memory device 101. In certain embodiments, user data may be provided by controller 106 to non-volatile memory, such as by utilizing a memory interface. For example, the user data may be obtained from the host device 103 to be stored in the non-volatile memory. In certain embodiments, the controller 106 may include an encoder for generating ECC data (e.g., such as when writing data to the non-volatile memory), and decoder for decoding ECC data (e.g., when reading data, such as from the non-volatile memory). In certain embodiments, the controller 106 may include firmware, which may be configured to control the components of the system 100. In certain embodiments, the firmware may be configured to control access to the non-volatile memory by the host device 103 and control the operative functionality of the memory device 101.

As indicated above, the memory device 101 may be configured to receive data (e.g., user data) to be stored from a host device 103 (e.g., over a serial communications interface, or a wireless communications interface). In certain embodiments, the user data may be video data from a device of a user, sensor data from one or more sensors of an autonomous or other vehicle, text data, audio data, virtual reality data, augmented reality data, information, content, any type of data, or a combination thereof. In certain embodiments, memory device 101 may be configured to store the received data in memory cells 110 and storage cells 112 of a memory array 102. In certain embodiments, the memory cells 110 may be provided by one or more volatile or non-volatile memory chips. In one example, the memory chips may be NAND-based flash memory chips, however, any type of memory chips or combination of memory ships may also be utilized. In certain embodiments, the memory device 101 may be configured to store received data in memory cells 110 of volatile memory on a non-persistent basis. In certain embodiments, the memory cells 110 may be configured to store data on a short-term basis, which may be configured to be lost when power is no longer supplied to the memory device 101. In certain embodiments, the storage cells 112 may be configured to store data on a long-term or persistent basis, irrespective of whether the power is supplied to the memory device 101 or not. In certain embodiments, the memory cells 110 may be made of a first chalcogenide material composition and the storage cells 112 may be made of a second chalcogenide material composition. In certain embodiments, the first chalcogenide material composition utilized for the memory cells 110 may be different from the second chalcogenide material composition utilized for forming the storage cells 112.

In certain embodiments, the memory array 102 including the memory cells 110 and storage cells 112 may be configured to be arranged in a 3D architecture, such as, but not limited to, a cross-point architecture to store data. In certain embodiments, each memory cell 110 and each storage cell 112 may be formed using a single select (SD) device. In certain embodiments, single select device may include a chalcogenide material that may be configured to switch or snap when a sufficient voltage is applied across the memory cells 110, storage cells 112, or a combination thereof. In certain embodiments, the cells in the memory array 102 may represent a first logic state (e.g., a logic 1) associated with a first set of threshold voltages, or a second logic state (e.g., a logic 0) associated with a second set of threshold voltages. In certain embodiments, the memory cells 110, the storage cells 112, or a combination thereof, may be arranged in a 3D vertical architecture. In certain embodiments, the 3D vertical architecture may include memory cells 110, storage cells 112, or a combination thereof, located a crossing between a vertical access line (e.g., a bit line pillar), and each of a plurality of second access lines (e.g., word lines) that may be formed in a horizontal plane or deck parallel to each other.

In certain embodiments, the memory device 102 may include any number of hardware security modules (not explicitly shown). In certain embodiments, the hardware security modules may include an interface that facilitates communications to and from the host device 103. In certain embodiments, the interface can comprise a Peripheral Component Interconnect Express (PCIe) interface or other interface. In certain embodiments, the interface can comprise other similar types of interfaces such as a Non-Volatile Memory Express (NVMe), NVMe over Fiber (NVMeOF), Serial Peripheral Interface (SPI), or similar bus. In certain embodiments, the hardware security modules may be configured to receive commands from host device 103, such as via an interface. In certain embodiments, the commands can comprise commands that are to be executed in a secure manner. For example, the commands can comprise commands to generate or derive cryptographic keys, read cryptographic keys, encrypt or decrypt data, generate digital signatures, etc. In certain embodiments, any commands currently executable by existing hardware security modules can be received via the interface.

In certain embodiments, hardware security modules may include a physical unclonable or physically unclonable function (PUF). In certain embodiments, the PUF may comprise a physical hardware circuit that exploits inherent randomness introduced during manufacturing to give a physical entity a unique ‘fingerprint’ or trust anchor. In certain embodiments, the PUF may produce a consistent and repeatable value. In certain embodiments, the PUF may comprise a SRAM PUF, Delay PUF, or any other PUF technology implemented on the hardware security modules. In certain embodiments, the hardware security modules may create a PUF from a portion of uninitialized memory space in the volatile storage area that is not subsequently used for any other purpose. Thus, the PUF 140 value may be related to the random value of the portion of the memory space in the volatile storage area. In certain embodiments, by not storing keys, the hardware security modules may not be susceptible to offline attacks. Further, in certain embodiments, security requirements can be relaxed since keys are only stored in volatile storage area and not persistent memory. In certain embodiments, firmware of the memory device 101 may be configured to control the operative functionality of the memory device 101. In certain embodiments, the firmware 101 may be configured to manage all operations conducted by the controller 106.

In certain embodiments, the memory device 101 may be configured to include bias circuitry 124. In certain embodiments, the bias circuitry 124 may be configured to apply voltages to the memory cells 110 and storage cells 112 in the memory array 102, such as when performing operations with respect to the memory array 102. For example, the bias circuitry 124 may be configured to apply voltages to the memory cells 110 and storage cells 112 when performing read, write, or even erase operations. In certain embodiments, the bias circuitry 124 may be configured to generate voltages for applying write voltages to memory cells 110 and storage cells 112. In certain embodiments, the bias circuitry 124 may be configured to generate read voltages for read operations performed on the memory array 102, such as in response to a command issued by the host device 103. In certain embodiments, the bias circuitry 124 may be controlled by utilizing the controller 106.

In certain embodiments, the memory device 101 may include sensing circuitry 122 configured to sense a current associated with each of the memory cells 110, storage cells 112, or a combination thereof. In certain embodiments, the sensing circuitry 122 may be configured to read or sense the memory cells 110, the storage cells 112, or a combination thereof, to determine a state, such as a stored state, of the memory cells 110, the storage cells 112, or a combination thereof. In certain embodiments, the sensing circuitry 122 may be configured to include sense amplifiers to detect a current caused by applying various voltages to memory cells in the memory array 102. In certain embodiments, the bias circuitry 124 may be configured to apply a pre-read voltage to the memory cells 110, storage cells 112, or a combination thereof. The sensing circuitry 122 may be configured to sense a current associated with each of the memory cells 110, storage cells 112, or a combination thereof, that is caused based on application of the pre-read voltage.

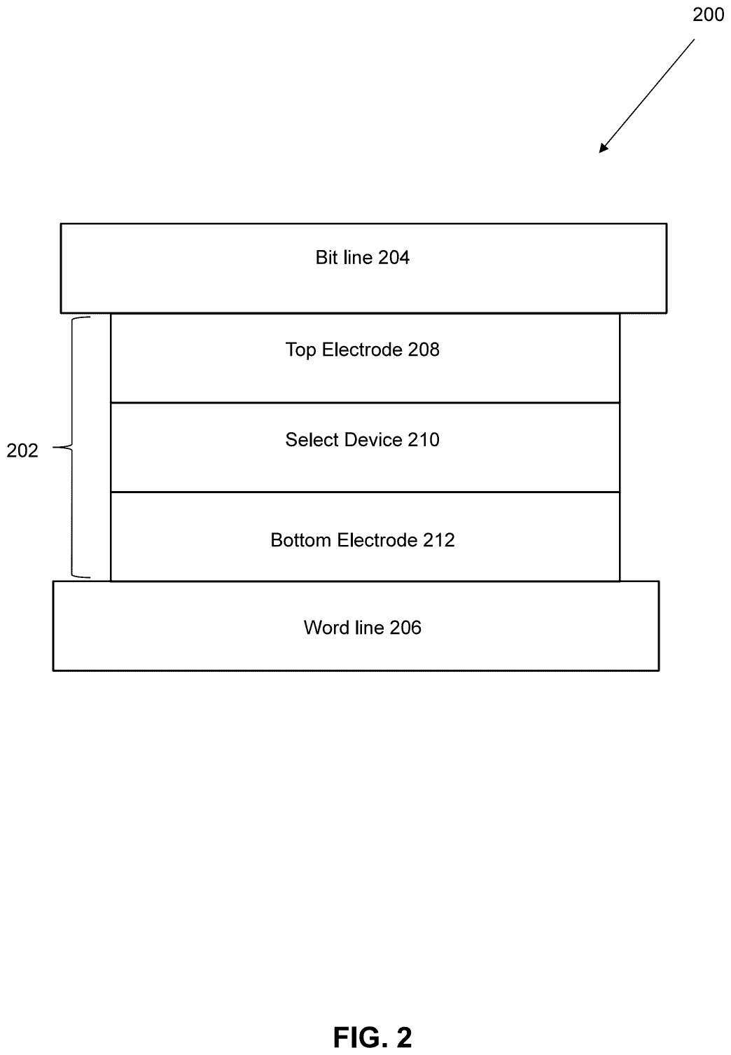

Referring now also to FIG. 2, FIG. 2 illustrates an exemplary memory device 200 including a select device 210 is schematically shown. In certain embodiments, the memory device 200 may be a memory cell 202, a storage cell 202, or a combination thereof. In certain embodiments, the select device 210 may include a chalcogenide material composition, such as a chalcogenide material, chalcogenide alloy, or a combination thereof. For example, in the context of memory cells 110, the chalcogenide composition may include XMC18 (1.5V @1 us). In the context of storage cells 112, the chalcogenide composition may include XMA2 (1.5V @1 us) for Storage+ and XMA2/XMC (1.5 v @ 1 us) for managed storage (i.e., SCM). Memory cell 202 (or storage cell 202) may correspond with memory cells 110 (or storage cells 112) from FIG. 1. In certain embodiments, the top electrode 208 may conductively connect select device 210 to the bit line 204. Similarly, the bottom electrode 212 may conductively connect select device 210 to the word line 206. In certain embodiments, the top electrode 208 and bottom electrode 212 may be made of carbon or carbon-related materials.

In certain embodiments, threshold voltage properties of the select device may be based on the voltage polarities applied to the memory cell 202 (or storage cell 202). In certain embodiments, a logic state may be written to memory cell 202 (or storage cell 202), which may correspond to one or more bits of data. In certain embodiments, a logic state may be read from or written to the memory cell 202 (or storage cell 202) by applying voltages of different polarities at different voltage magnitudes, current magnitudes, or a combination thereof. The reading and writing protocols may take advantage of different threshold voltages of the select device 210 that may result from the different polarities.

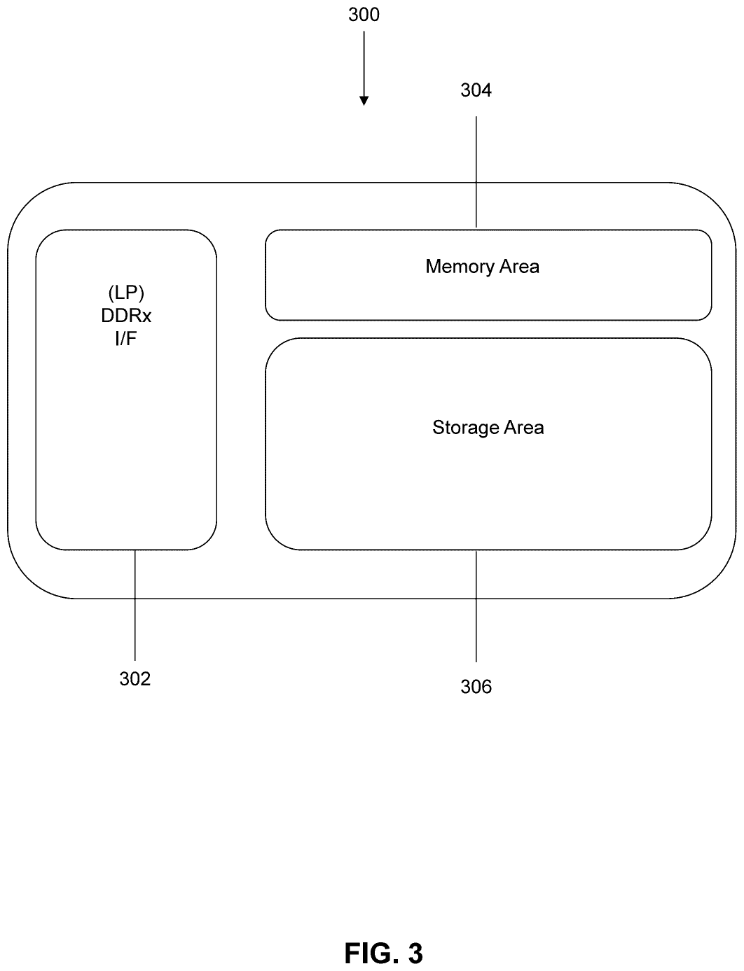

Referring now also to FIG. 3, another exemplary memory device 300 is shown. The memory device 300 may include a (LP) DDrx interface 302, a memory area 304, and a storage area 306. In certain embodiments, the memory area 304 may include a differential cell that may be configured to have persistency (e.g., long-term storage), PIM possibility, dynamic allocation, among other functionalities. In an exemplary embodiment, the memory area 304 may be a differential cell with 60 nS latency, <1 e-7 RBER 64B access. In certain embodiments, the storage area 306 may be a managed storage (SCM) that may be configured to minimize external swags to NAND bulk archives. The SCM may also be configured to minimize time and energy with internal swaps. The SCM may also be configured to provide quality response capability and quality of service. In an exemplary embodiment, the storage area 306 may be a managed storage with 250 nS latency, self-managed capability, internal BCH3, among other features. In certain embodiments, as shown, the memory area 304 and storage area 306 may be configured to reside on the same memory chip (e.g., memory device 300).

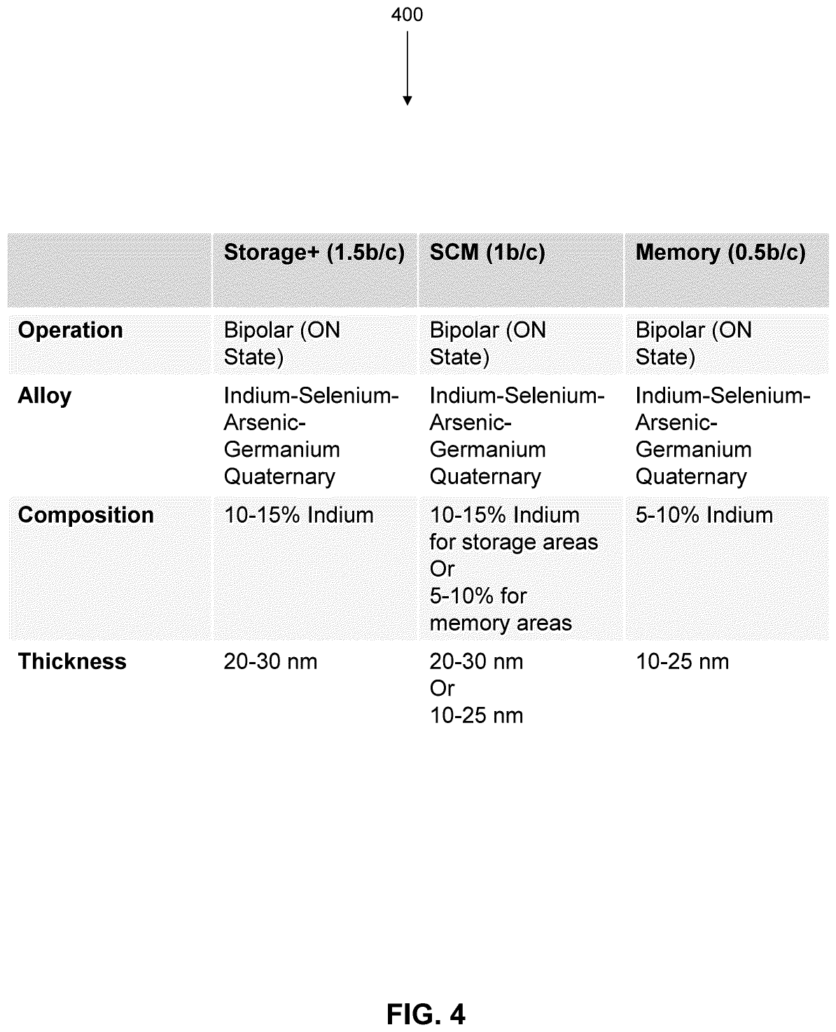

Referring now also to FIG. 4, exemplary characteristics and chalcogenide materials that may be utilized to implement memory areas and storage areas for a memory array (e.g., memory array 102) on a single chip in accordance with embodiments of the present disclosure are shown in table 400. In certain embodiments, the chalcogenide materials utilized for the memory areas and storage areas may include alloy compositions, such as, but not limited to, alloy compositions from the Indium-Selenium-Arsenic-Germanium quaternary diagram. In certain embodiments, varying percentages of each element (i.e., Indium, Selenium, Arsenic, and Germanium) may be utilized for the memory areas and storage areas for the memory array. For example, for a memory device incorporating a storage area, Storage+ (1.5b/c) the bipolar operation (ON State) may be utilized for the memory array and the chalcogenide alloy may comprise 10-15% Indium, with various percentages of Selenium, Arsenic and Germanium. In certain embodiments, the storage area, Storage+, may operate at 1.5 v @ 1 us, however, other voltage windows and times may be utilized. In certain embodiments, the chalcogenide alloy composition for the storage area may, in a preferred, embodiment, be in a range of 20-30 nm in thickness and may be generated based on ALD deposition. In certain embodiments, a motivation for using Storage+ may be for retention (e.g., >4 m @55 C) and MLC capability (e.g., 1.5b/cell). As another example, for a memory device incorporating SCM (1/b/c), the bipolar operation (ON State) may be utilized for the memory array and the chalcogenide alloy may comprise 10-15% Indium with varying percentages of Selenium, Arsenic, and Germanium, however, in other embodiments, the chalcogenide alloy may comprise 5-10% Indium with any variation of percentages of Selenium, Arsenic, and Germanium. In certain embodiments, the chalcogenide alloy may operate at 1.5 v @lus, however, other voltage windows and times may be utilized. In certain embodiments, the chalcogenide alloy composition for the SCM may, in a preferred, embodiment, be in a range of 10-25 nm or in a range of 20-30 nm in thickness and generated based on ALD deposition. A motivation for using SCM may be for better retention for the 10-15% Indium composition and low programming current for the 5-10% Indium chalcogenide composition. As a further example, for a memory device incorporating a memory area (e.g., 0.5b/c) the bipolar operation (ON State) may be utilized for the memory array and the chalcogenide alloy composition may comprise 5-10% Indium with any variation of percentages of Selenium, Arsenic, and Germanium. In certain embodiments, the chalcogenide alloy composition may operate at 1.5V @1 us, however, other voltage windows and times may also be utilized. In certain embodiments, the chalcogenide alloy composition for the memory area may, in a preferred, embodiment, be in a range of 10-25 nm in thickness and may be generated based on ALD deposition. A motivation for using memory (e.g., 0.5b/c) may be for the low programming current (>10 uA) and better RD immunity.

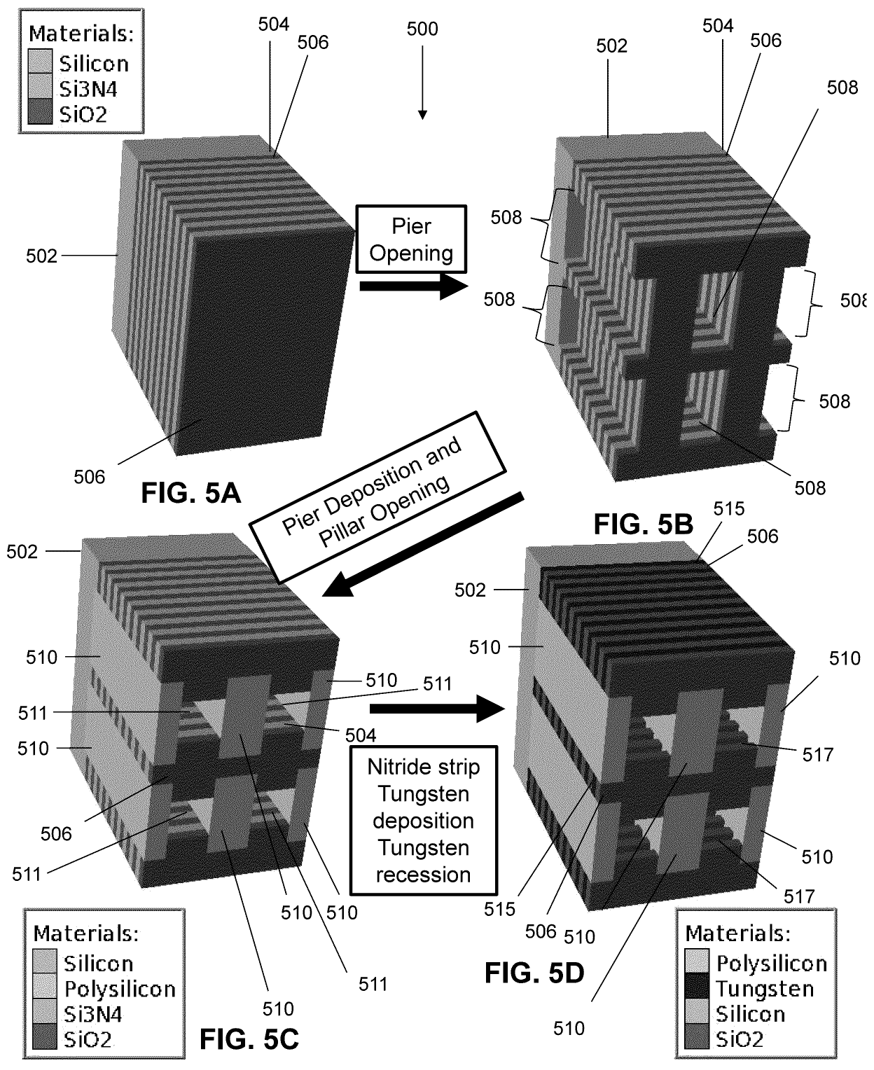

Referring now also to FIGS. 5A, 5B, 5C, 5D, 6A, 6B, 7A, 7B, 8, 9A, 9B, and 10, an exemplary memory array 500 incorporating both memory cells and storage cells within the same chip is shown. Additionally, the process by which the memory array 500 is created is also shown in FIGS. 5A, 5B, 5C, 5D, 6A, 6B, 7A, 7B, 8, 9A, 9B, and 10. For the sake of simplicity, these Figures illustrate single pillars on which two different processes are run to incorporate the memory cells and storage cells. In a real-world example, the two processes may be applied to wide groups of contiguous memory cells, which may be macroscopically separated. To that end, in FIG. 5A, an initial structure to create a memory array 500 is shown. The initial structure may be created by depositing a plurality of silicon nitride (Si₃N₄) layers 504 and silicon dioxide (SiO₂) layers 506 onto a silicon layer 502 that may serve as a base for the memory array 500. In certain embodiments, as shown in FIG. 5A, alternating layers 504, 506 of silicon nitride and silicon dioxide may be deposited onto the silicon layer 502.

Once the silicon nitride layers 504 and silicon dioxide layers 506 are deposited onto the silicon layer 502, the next step may be to create a series of pier openings 508, as shown in FIG. 5B. In certain embodiments, the pier openings 508 may be created based on etching away a portion of the silicon nitride layers 504 and silicon dioxide layers 506 on either side of the memory array 500 structure and etching away portions of the layers 504, 506 in the middle of the memory array 500 structure. Once the pier openings 508 are created, the next step, as shown in 5C, may include conducting pier deposition and creating pillar openings. In certain embodiments, for example, piers 510 may be deposited into or onto each pier opening 508. In certain embodiments, the piers 510 may be made of polysilicon, any other suitable material, or a combination thereof. Additionally, pillar openings 511 may also be created based on etching away a portion of the silicon nitride and silicon dioxide layers 504, 506. In FIG. 5C, four pillar openings 511 may be created, which may extend through some or all of the length of the silicon nitride and silicon dioxide layers 504, 506. In certain embodiments, a greater or lesser number of pillar openings 511 may be created.

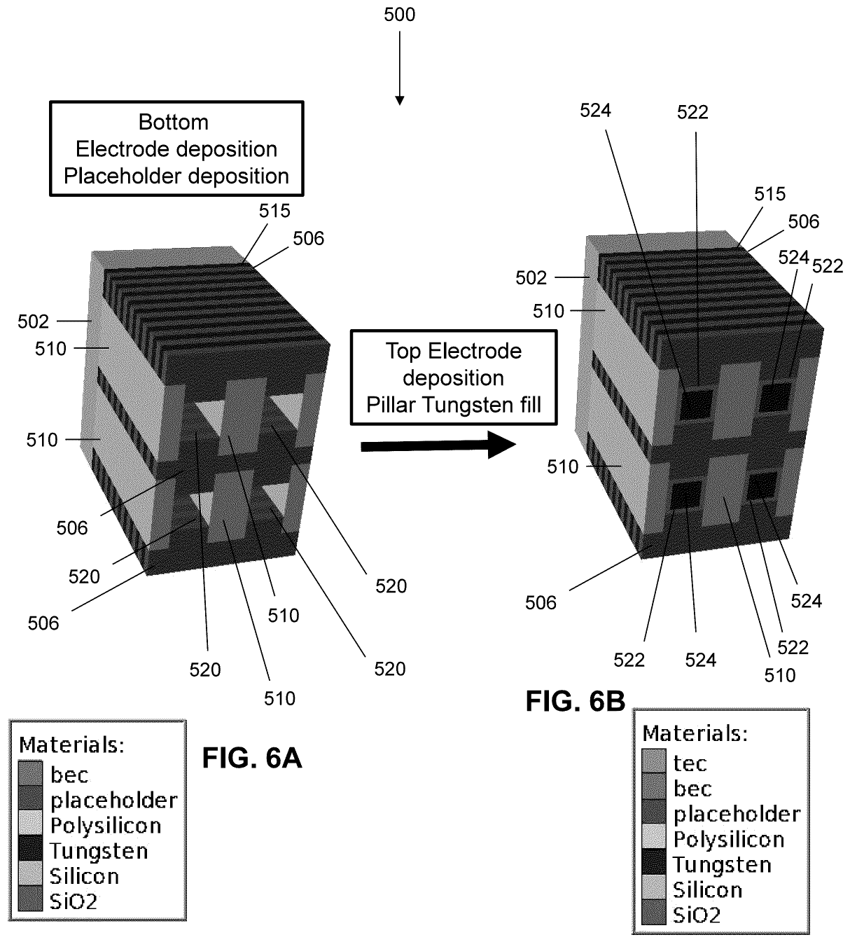

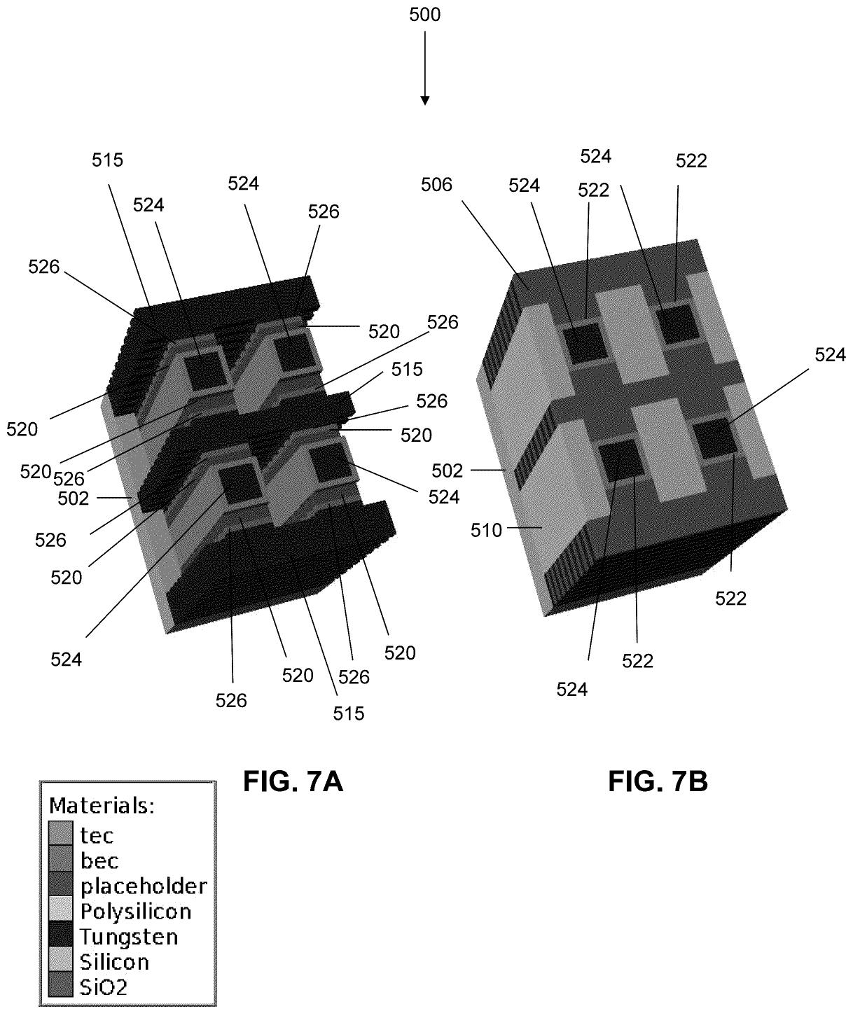

Once the piers 510 are deposited and the pillar openings 511 are created, the remaining silicon nitride layers 504 may be stripped away from the memory array structure, as shown in FIG. 5D. After the silicon nitride layers 504 are stripped away, tungsten layers 515 may be deposited where the silicon nitride layers 504 were stripped. For example, as shown in FIG. 5D, once the tungsten layers 515 are deposited, the tungsten 515 layers may alternate with the remaining silicon dioxide layers 506. In certain embodiments, a tungsten layer 506 recession process may then be performed, which may recede a portion of the tungsten, such as at the base of the pillar openings 511, so that recesses 517 are created within the memory array structure. Referring to FIG. 6A, after the recesses 517 are created after removing a portion of the tungsten layers 515, a bottom electrode 526 may be deposited into the structure of the memory array 500. For example, the deposited bottom electrode 526 may be readily seen in FIGS. 7A, 9B, and 10. Additionally, in certain embodiments, placeholder material 520 may be deposited in the recesses 517.

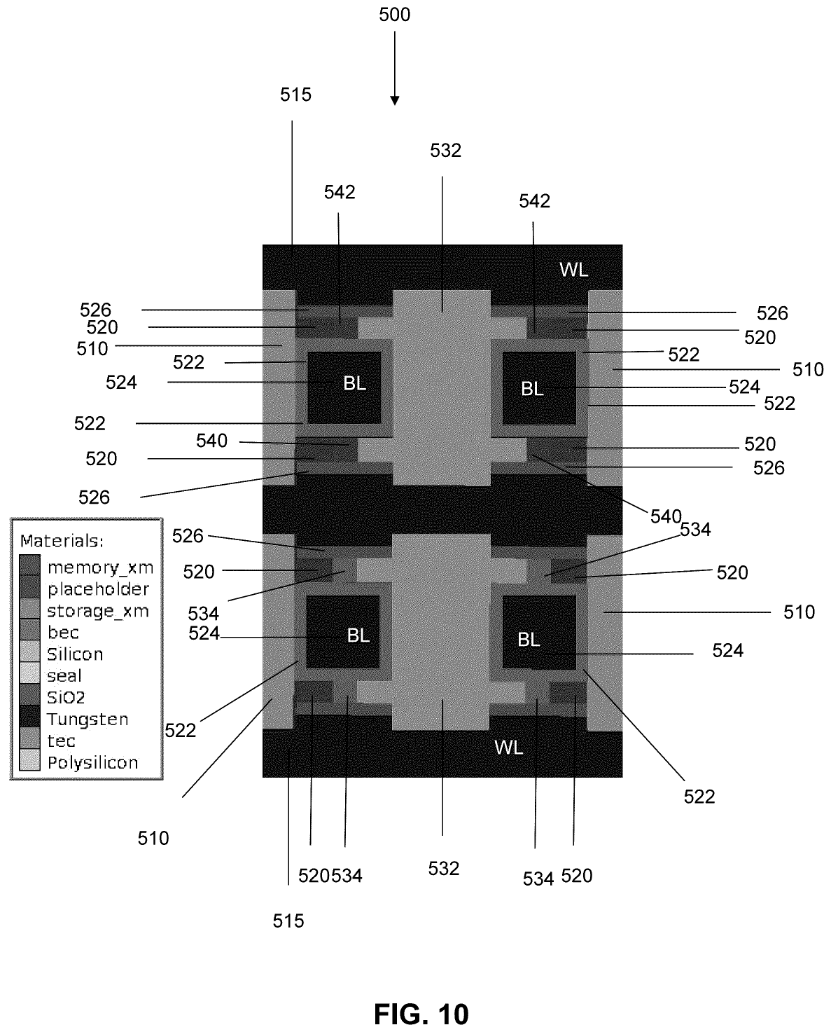

After the placeholder material 520 is deposited into the recesses 517 and referring to FIG. 6B, the top electrode(s) 522 may be deposited into the memory array structure. The process may the include performing a filling operation on the memory array structure. The filling operation may include filling the pillar openings 511 with tungsten 524 material through some or all of the length of the pillar openings 511. The tungsten 524 filled in the pillar openings 511 may be utilized to create bitlines (BL), as shown in FIG. 10. The wordlines (WL) are shown as being at the top and bottom, as shown in FIG. 10. In certain embodiments, the tungsten 524 may be configured to be enveloped by the top electrode 522 around the outer surface of the tungsten 524. Next, the placeholder material 520 is the next area to be reached for creation of the memory array 500 following the covering of the recesses 517 and deposition through utilizing polysilicon etching. The creation of the memory cells (e.g., for memory select device) and storage cells (e.g., for storage select device) for the memory array 500 comes next. For visualization purposes, the polysilicon for the piers 510 have been removed and the silicon dioxide layers 506 have been removed in FIG. 7A. In FIG. 7B, the polysilicon for the piers 510 and the silicon dioxide layers 506 are intact.

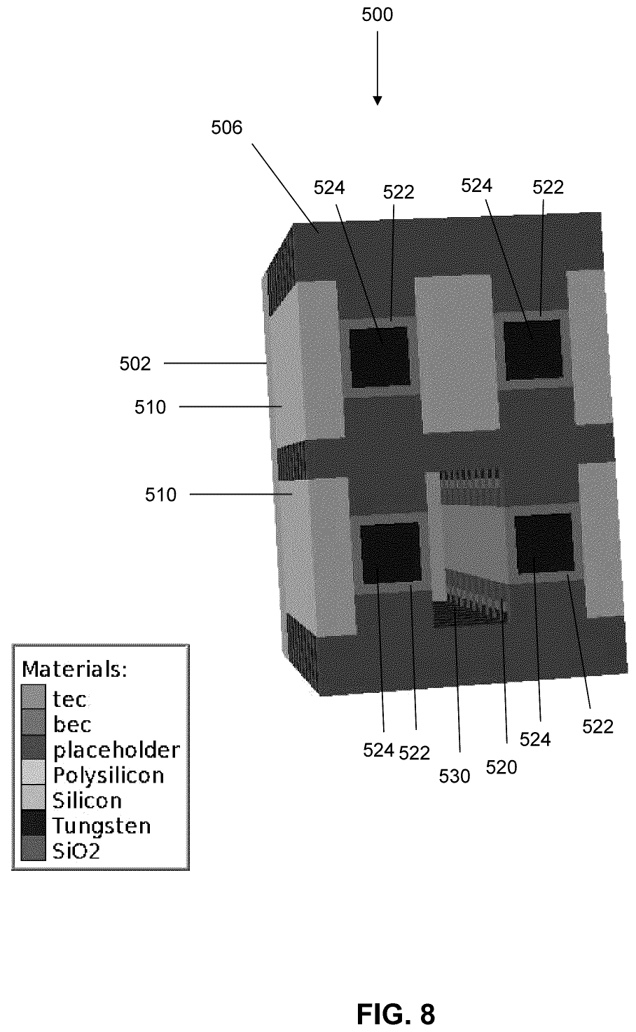

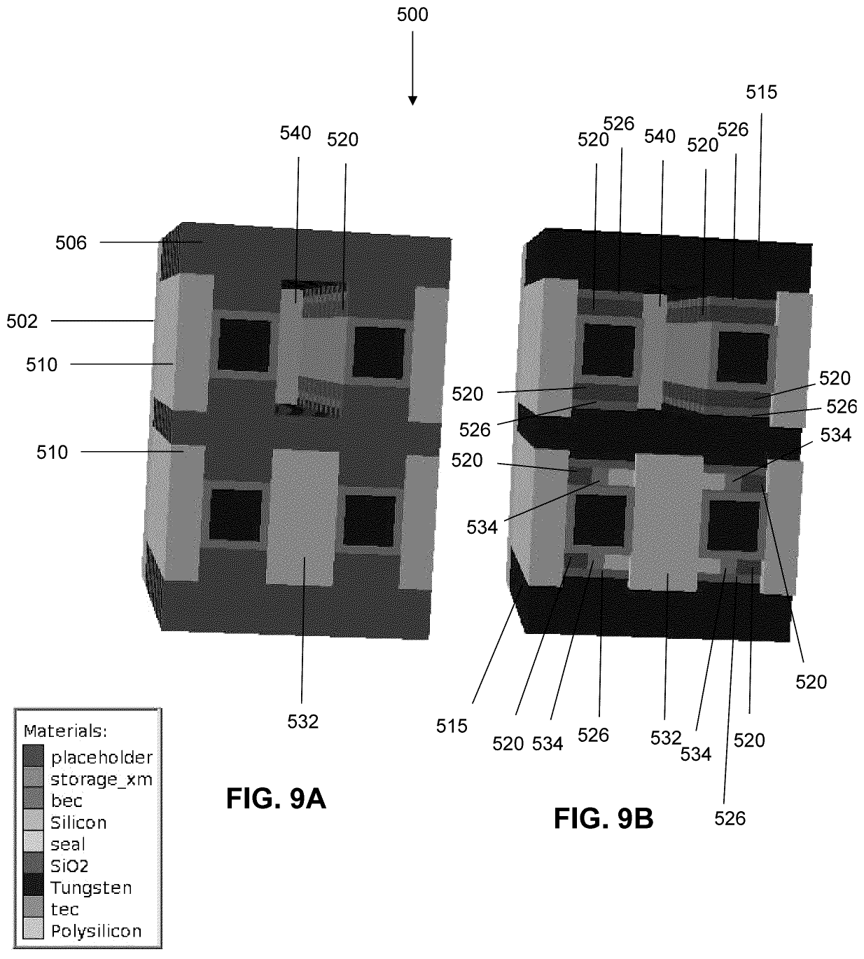

Referring now also to FIG. 8, a first opening 530 is to be created in the memory array structure. In certain embodiments, a pier 510 comprising polysilicon may be etched to create the first opening 530, which may be configured to reside between the bottom tungsten-filled pillars of the memory array structure, as shown in FIG. 8. For example, in FIG. 8, the middle bottom polysilicon pier 510 is etched to create the first opening extending within the memory array structure. In certain embodiments, the polysilicon pier 510 is etched to gain access to the placeholder material 520 deposited within the memory array structure. Next, a portion of the placeholder material 520 accessible via the first opening 530 may undergo a recession process to remove the portion of the placeholder material 520. Once the recission process of completed, the storage cells 534 may be deposited or otherwise incorporated in the location where the portion of the placeholder material was removed via the first opening 530. Referring now also to FIG. 9B, the storage cells 534 are readily shown. In certain embodiments, the storage cells 534 may be made of a first chalcogenide material as described herein. Once the storage cells 534 are deposited or otherwise incorporated, a sealing material be utilized to create a seal 532 to close the first opening 530.

Once the first opening 530 is sealed after deposition of the storage cells 534 made of the first chalcogenide material composition, the second opening 540 may be created. The second opening 530 may be created based on etching a polysilicon pier 510, which may be configured to reside between the top tungsten-filled pillars of the memory array structure, as shown in FIGS. 9A and 9B. As with the process for creating the first opening 530, the polysilicon etch may be utilized to access placeholder material 520. Once the second opening 540 is created, a portion of the placeholder material 520 accessible via the second opening 540 may undergo a recession process to recede away and remove a portion of the placeholder material 520. After the portion of the placeholder material 520 is removed, the memory cells 542 (e.g., for memory select device) may be deposited or otherwise incorporated at the locations where the portion of the placeholder material 520 was removed via the second opening 540. In certain embodiments, the memory cells 542 deposited via the second opening 540 may be comprised of a different chalcogenide material composition than used for the storage cells 534. Once the memory cells 542 are deposited or otherwise incorporated, the memory cells 542 and the storage cells 534 are now with the same formed memory array 500. In certain embodiments, the memory cells 542 and the storage cells 534 may be independently addressed by utilizing proper wordline and bitline selection. The final memory array 500 is illustrated in FIG. 10

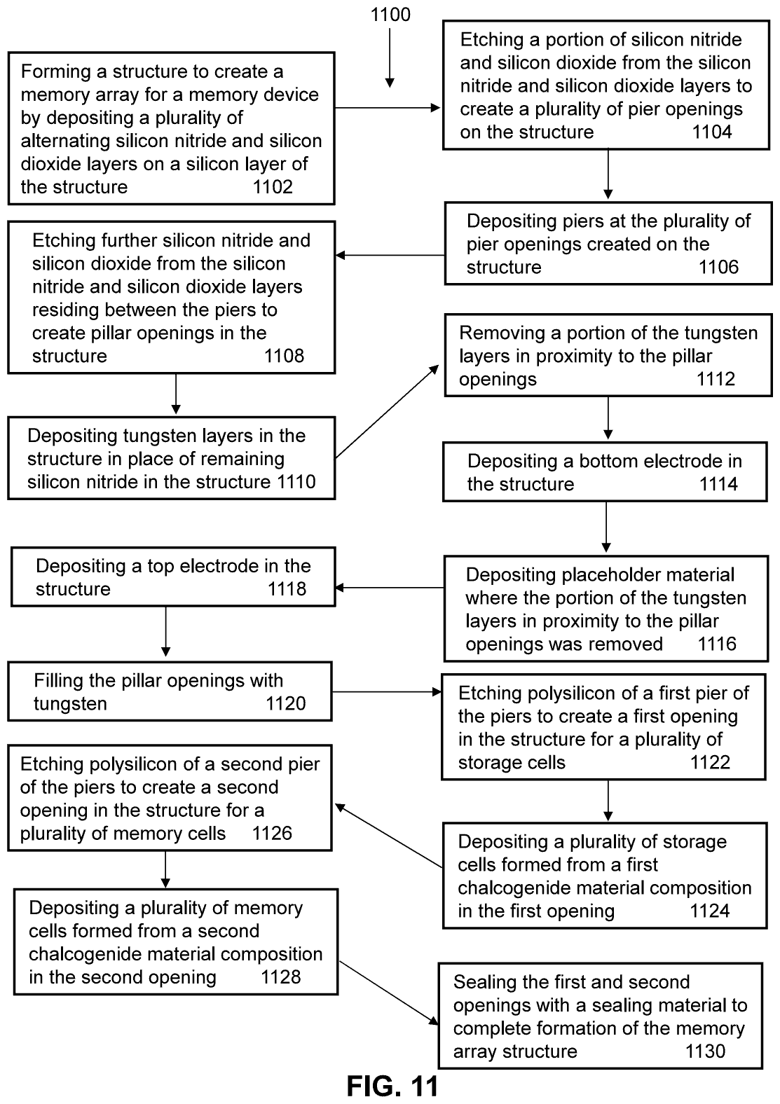

Referring now also to FIG. 11, FIG. 11 illustrates a method 1100 for forming a memory array include both memory cells and storage sells on a single chip or device according to embodiments of the present disclosure. For example, the method of FIG. 11 can be utilized to implement some or all of the system 100 of FIG. 1, the memory cell 200, the chip 300, the memory array 500 in FIGS. 5, 6, 7, 8, 9, and 10, and any of the other systems or devices illustrated in the Figures. In certain embodiments, the method of FIG. 11 can be performed by devices and systems capable for creating memory arrays, depositing various layers to create memory arrays, conducting recession processes, conducting sealing of openings, any of the other operative steps or functionality described herein, or a combination thereof, such as those devices and systems found in a memory fabrication facility. Although shown in a particular sequence or order, unless otherwise specified, the order of the processes may be modified as desired or necessary. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 110 may include steps for creating a memory array including both storage cells and memory cells that are formed using two different chalcogenide material compositions according to various embodiments of the present disclosure. In certain embodiments, the method 1100 may be performed by any appropriate memory manufacturing machinery and processes, and steps may be initiated by utilizing various combinations of processors, memories, and other componentry capable of instructing the manufacturing machines to execute processes to perform the steps of the method 1100. At step 1102, the method 1100 may begin by forming a structure to initiate creation of a memory array (e.g., memory array 102) for use in a memory device (e.g., memory device 101). In certain embodiments, the initial structure for the memory array may be generated by depositing a plurality of silicon nitride (Si₃N₄) layers and silicon dioxide (SiO₂) layers onto a silicon layer (e.g., as shown in FIG. 5A). In certain embodiments, the silicon nitride and silicon dioxide layer may be deposited in alternating layers onto the silicon (e.g., as shown in FIG. 5A).

At step 1104, the method 1100 may include etching a portion of silicon nitride and silicon dioxide from the silicon nitride and silicon dioxide layers to create a plurality of pier openings (e.g., pier openings 508) on the structure creating the memory array. In certain embodiments, for example, the etching may include any type of etching technique, including, but not limited to, application of wet acid or plasma dry gas to remove the silicon nitride and silicon dioxide from the corresponding layers. At step 1106, the method 1100 may include depositing piers at the plurality of pier openings created on the structure. In certain embodiments, the piers may comprise polysilicon, any other suitable material, or a combination thereof. In certain embodiments, a total of six piers may be deposited within six pier openings created on the structure. At step 1108, the method 1100 may include etching further silicon nitride and further silicon dioxide from the silicon nitride and silicon dioxide layers residing between the deposited piers to create pillar openings in the structure. For example, as shown in the Figures, pillar openings 511 may be created based on removing silicon nitride and silicon dioxide residing between the piers 510.

At step 1110, the method 1100 may include stripping remaining silicon nitride from the memory array structure. For example, the remaining silicon nitride may be stripped so that tungsten layers may be deposited where in place of the silicon nitride, as shown in FIG. 5D. In certain embodiments, when the tungsten layers are deposited in place of the silicon nitride that was stripped, the tungsten layers (e.g., tungsten layers 515) may alternate with the silicon dioxide layers, as shown in FIG. 5D. At step 1112, the method 1100 may include removing a portion of the tungsten layers, such as the portions in proximity to the pillar openings. For example, as shown in FIG. 5D, tungsten may be removed or recessed from the interior of the structure, such as between the piers 510. At step 1114, the method 1100 the method 1100 may include depositing a bottom electrode(s) in the structure. For example, bottom electrodes 526 may be deposited within the structure, as shown in FIG. 6A and visualized in FIG. 9B and FIG. 10.

At step 1116, the method 1100 may include depositing placeholder material where the portion of the tungsten layers in proximity to the pillar openings was removed. For example, the deposited placeholder material 520 is shown in FIGS. 6A and 7A and is shown as alternating with the silicon dioxide layers 506. At step 1118, the method 1100 may include depositing a top electrode(s) in the structure. For example, the deposited top electrode(s) is shown in FIGS. 6B, 7A, 7B, 8, 9A, 9B, and 10. At step 1120, the method 1100 may include filling the pillar openings. For example, in certain embodiments, the pillar openings 511 may be filled with tungsten 524. The top electrode 522 may be configured to envelope around the tungsten 524. At step 1122, the method 1100 may include etching polysilicon of a first pier of the piers to facilitate creation of a first opening (e.g., opening 530) in the structure that may be configured to receive a plurality of storage cells. For example, as shown in FIG. 8, the polysilicon of the middle bottom pier 510 may be etched away so that access may be provided to the placeholder material 520 contained with the structure 500. At step 1122, the method 1100 may also include conducting recession of a portion of the placeholder material so that storage cells (e.g., storage cells 534) may be deposited in place of the portion of the placeholder material that has been removed.

At step 1124, the method 1100 may include depositing or otherwise incorporating a plurality of storage cells formed from a first chalcogenide material composition in place of the portion of the placeholder material via the first opening. For example, FIGS. 9B and 10 illustrate the deposited (or otherwise incorporated) storage cells deposited adjacent to a portion of the existing placeholder material. At step 1126, the method 1100 may include etching polysilicon of a second pier of the piers to facilitate creation of a second opening in the structure that may be configured to receive a plurality of memory cells. For example, as shown in FIGS. 9A and 9B, the polysilicon of the middle top pier 510 may be etched away so that access may be provided to the placeholder material 520 contained within the structure 500. At step 1128, the method 1100 may include depositing or otherwise incorporating a plurality of memory cells formed from a second chalcogenide material composition in place of a portion of placeholder material accessible via the second opening. For example, the second opening 540 may be accessed and a portion of the placeholder material 520 may be recessed away so that the memory cells may be deposited or otherwise incorporated in place of the portion of the placeholder material that has been removed. In certain embodiments, the second chalcogenide material for the memory cells may be a different chalcogenide material composition from the first chalcogenide material composition utilized for the storage cells. For example, the first chalcogenide material utilized for the storage cells may comprise alloy XMA2 (1.5V @ 1 us) or alloy XMA2/XMC (1.5V @ 1 us) and the second chalcogenide material utilized for the memory cells may comprise alloy XMC18 (1.5V @ 1 us) or other suitable chalcogenide material. At step 1130, the method 1100 may include sealing the first and second openings with a sealing material to secure the componentry and secure the componentry in place. For example, sealing material 532 may be utilized to seal the first opening 530 and the second opening 540 to secure the storage and memory cells for the memory array contained within the structure. Once the sealing material is applied, the memory array including both storage cells and memory cells may be completed and then incorporated into a device, such as a computing device. Notably, the method 1100 may incorporate any of the features and functionality described elsewhere in the present disclosure and is not limited to the specific steps or sequence of steps illustrated in FIG. 11.

Reference in this specification to “one embodiment” “an embodiment” or “certain embodiments” may mean that a particular feature, structure, or characteristic described in connection with the embodiment is included in at least one embodiment of the disclosure. The appearances of the phrases “in one embodiment” and “in certain embodiments” in various places in the specification are not necessarily all referring to the same embodiment(s), nor are separate or alternative embodiments mutually exclusive of other embodiments. Moreover, various features are described which may be exhibited by some embodiments and not by others. Similarly, various requirements are described which may be requirements for some embodiments, but not other embodiments.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. A memory device, comprising:
a memory array configured to store data;
wherein the memory array comprises a plurality of storage cells, wherein the plurality of storage cells comprise a first chalcogenide material composition; and
wherein the memory array comprises a plurality of memory cells, wherein the plurality of memory cells comprise a second chalcogenide material composition different from the first chalcogenide material composition of the plurality of storage cells.

2. The memory device of claim 1, wherein the memory array comprises a silicon layer and a plurality of alternating silicon dioxide and tungsten layers.

3. The memory device of claim 1, wherein the plurality of storage cells and the plurality of memory cells reside on a single chip.

4. The memory device of claim 1, further comprising a plurality of piers positioned in proximity to the plurality of storage cells and the plurality of memory cells, wherein the plurality of piers comprise polysilicon.

5. The memory device of claim 1, further comprising first placeholder material positioned adjacent to the first chalcogenide material composition of the plurality of storage cells and to a first polysilicon pier of the memory array.

6. The memory device of claim 5, further comprising second placeholder material adjacent to the second chalcogenide material composition of the plurality of memory cells and to a second polysilicon pier of the memory array.

7. The memory device of claim 1, further comprising a top electrode in a structure of the memory array, wherein the top electrode surrounds bitlines of the memory array.

8. The memory device of claim 1, further comprising a bottom electrode in a structure of the memory array, wherein the bottom electrode is in contact with the first chalcogenide material composition, the second chalcogenide material composition, or a combination thereof.

9. The memory device of claim 1, further comprising a plurality of bitlines positioned in proximity to a plurality of piers of the memory array, a top electrode, the first chalcogenide material composition, the second chalcogenide composition, or a combination thereof, wherein the plurality of bitlines comprise tungsten.

10. The memory device of claim 1, further comprising a plurality of wordlines in contact with a bottom electrode and a plurality of piers of the memory array, wherein the plurality of wordlines comprise tungsten.

11. The memory device of claim 1, further comprising a sealing material to seal the memory cells, the storage cells, or a combination thereof, within a structure of the memory array.

12. The memory device of claim 1, wherein the plurality of memory cells and the plurality of storage cells are configured to be independently addressed based on wordline and bitline selection.

13. The memory device of claim 1, wherein the first chalcogenide material composition comprises an chalcogenide alloy composition comprising 10 to 15% Indium and percentages of one or more of Selenium, Arsenic, and Germanium, and wherein the second chalcogenide material composition comprises a chalcogenide alloy composition comprising 5 to 10% Indium and percentages of one or more of Selenium, Arsenic, and Germanium.

14. A method, comprising:
forming a structure to create a memory array for a memory device by depositing a plurality of alternating silicon nitride and silicon dioxide layers on a silicon layer of the structure;
etching a portion of silicon nitride and silicon dioxide from the silicon nitride and silicon dioxide layers to create a plurality of pier openings on the structure;
depositing piers at the plurality of pier openings on the structure;
etching further silicon nitride and silicon dioxide from the silicon nitride and silicon dioxide layers residing between the piers to create pillar openings in the structure;
depositing tungsten layers in the structure in place of remaining silicon nitride in the structure;
depositing a bottom electrode and a top electrode in the structure;
filling the pillar openings with tungsten;
incorporating a plurality of storage cells formed from a first chalcogenide material composition in a first opening created in the structure;
incorporating a plurality of memory cells formed from a second chalcogenide material composition in a second opening created in the structure, wherein the second chalcogenide material composition is different from the first chalcogenide material.

15. The method of claim 14, further comprising depositing placeholder material within the structure after creation of the pillar openings in the structure.

16. The method of claim 14, further comprising stripping the remining silicon nitride from the structure before depositing the tungsten layers in the structure.

17. The method of claim 14, further comprising creating the first opening by etching polysilicon of a first pier of the piers from the structure.

18. The method of claim 14, further comprising creating the second opening by etching polysilicon of a second pier of the piers from the structure.

19. The method of claim 14, further comprising sealing the first and second openings with a sealing material after depositing the plurality of storage cells and the plurality of memory cells in the structure.

20. The method of claim 14, further comprising forming the first chalcogenide material composition with 10 to 15% Indium and percentages one or more of Selenium, Arsenic, and Germanium, and forming the second chalcogenide material composition with 5 to 10% Indium and percentages one or more of Selenium, Arsenic, and Germanium.

21. The method of claim 20, wherein a thickness of the first chalcogenide material composition utilized for the plurality of storage cells ranges from 20 to 30 nanometers, and wherein a thickness of the second chalcogenide material composition utilized for the plurality of memory cells ranges from 10 to 25 nanometers.

22. A system, comprising:
a host device; and
a memory device comprising;
a memory array, the memory array comprising;
a plurality of storage cells, wherein the plurality of storage cells comprise a first chalcogenide material composition; and
a plurality of memory cells, wherein the plurality of memory cells comprise a second chalcogenide material composition, wherein the second chalcogenide material composition of the plurality of memory cells is different from the first chalcogenide material composition of the plurality of storage cells.
